(19) United States
(12) Patent Application Publication
(10) Pub. No.: US 2026/0241429 A1
(43) Pub. Date: Aug. 20, 2026

(54) MULTI-STATION ROTARY FULLY AUTOMATIC BEADING MACHINE FOR MICRO PROBES

(71) Applicant: SUZHOU UIGREEN MICRO&NANO TECHNOLOGY CO. LTD., Suzhou (CN)

(72) Inventors: Xiaochen QIAN, Suzhou (CN); Zhiwei Liu, Suzhou (CN)

(21) Appl. No.: 19/486,580

(22) PCT Filed: May 12, 2022
(86) PCT No.: PCT/CN2022/092337

§ 371 Date: Nov. 21, 2025

(30) Foreign Application Priority Data
Sep. 24, 2021 (CN) 202111118672.9

(51) Int. Cl. B21C 37/08

(52) U.S. Cl. CPC B21C 37/0807

(57) ABSTRACT

Please replace the following substitute abstract for the abstract currently on file:

The present invention discloses a multi-station rotary fully automatic beading machine for micro probes, wherein on a rotary table is provided with a plurality of clamping fixtures that form a feeding station, an beading station and a discharging station, and the machine platform is correspondingly provided with a feeding mechanism, a cutting mechanism, a positioning mechanism and a discharging mechanism, wherein the feeding mechanism feeds probes to the feeding station, the positioning mechanism abuts against the upper end of the probe to position the probe in a vertical direction, the cutting mechanism comprises a cutting section and a rotating section, the rotating section drives the probe to perform self-rotation, the cutting section comprises a driving assembly and forming tools, the driving assembly drives the forming tool to translate and cut the self-rotating probe to form a bead, and the discharging mechanism removes the beaded probe from the clamping fixture.

### TECHNICAL FIELD

The present invention relates to the technical field of micro probe processing apparatus, and particularly relates to a multi-station rotary fully automatic beading machine for micro probes.

### BACKGROUND

When testing the electrical performance of integrated circuits, conductors such as test probes or conductive adhesives are generally required. Test probes are used in test sockets or test contactors to provide electrical interconnection between test circuit boards and devices under test (DUT) such as electronic packages. Spring-loaded probes are formed by three basic components: plunger, spring, and barrel, which are riveted and pre-compressed using precision instruments, with the plunger and spring pre-installed within the barrel, and under normal conditions, the spring remains in a compressed state within the barrel. To prevent deformation recovery of the spring, the barrel requires a beading operation, wherein a small section of the barrel is compressed inward to form a beading groove, thereby restricting the spring from popping out. The beading of the barrel is primarily divided into open-end beading and middle beading, the forming process of which involves manual placement of pre-assembled semi-finished products into the beading machine, with foot-pedal activation to complete the beading operation. Due to the relatively small product dimensions (approximately 0.3 mm diameter), manual placement presents significant difficulty, imprecise positioning results in reduced efficiency and yield rates, poor product placement uniformity, and susceptibility to product scratching and material feeding failures.

### SUMMARY

### Technical Solution

The object of the present invention is to provide a multi-station rotary fully automatic beading machine for micro probes, primarily used for middle-beaded probes, which can solve problems such as product surface scratching, feeding difficulties, poor product forming consistency, and low production efficiency, can meet the automatic assembly requirements for products with diameters above 0.25 mm, and can improve product yield, production efficiency, and significantly save human resources.

To achieve the above object, the technical solution adopted by the present invention is: a multi-station rotary fully automatic beading machine for micro probes, comprising a machine platform, wherein a rotary table is arranged on the machine platform, a plurality of clamping fixtures for clamping probes are arranged on the rotary table, the plurality of clamping fixtures form a feeding station, beading station, and discharging station along a rotation direction of the rotary table, a feeding mechanism is arranged on the machine platform adjacent to the feeding station, the feeding mechanism is configured to feed probes to the feeding station, a cutting mechanism and a positioning mechanism are arranged on the machine platform adjacent to the beading station, the positioning mechanism abuts against an upper end of the probe to position the probe in a vertical direction, the cutting mechanism comprises a cutting section and rotating section, the rotating section drives the probe, which has been positioned in the vertical direction, to rotate on its own axis, the cutting section comprises a driving assembly and forming tools, the driving assembly drives the forming tool to translate and cut the self-rotating probe to form a beading, a discharging mechanism is arranged on the machine platform adjacent to the discharging station, the discharging mechanism removes the beaded probe from the clamping fixture.

As a further optimization, the feeding mechanism comprises a feeding disc, a feeding manipulator and a feeding chuck, wherein the feeding disc is mounted on the machine platform adjacent to the feeding station, the feeding chuck is arranged at the free end of the feeding manipulator, and is driven by the feeding manipulator to feed probes from the feeding disc to the feeding station.

As a further optimization, the positioning mechanism comprises a pressing cylinder and a pressing head, wherein the pressing head is arranged at the free end of the pressing cylinder, and is driven by the pressing cylinder to move downward and abut against the upper end of the probe at the beading station.

As a further optimization, the rotating portion comprises a lifting cylinder, a rotary motor and a magnet, wherein the rotary motor is arranged at a free end of the lifting cylinder, the magnet is arranged at a free end of the rotary motor, the lifting cylinder drives the magnet to move upward and be attracted to the clamping fixture, and the rotary motor drives the magnet to rotate thereby driving the clamping fixture and the probe to rotate coaxially.

As a further optimization, the clamping fixture comprises a base, a bearing sleeve, a ferrous rotating sleeve, a positioning sleeve, and a protective sleeve, wherein a first through hole is provided on the base, a second through hole coaxial with the first through hole is provided on the rotary table, the ferrous rotating sleeve is rotatably mounted within the bearing sleeve, the bottom end of the ferrous rotating sleeve is located at the first through hole and is magnetically attracted by the magnet, the positioning sleeve is fixed inside the ferrous rotating sleeve, and a protective sleeve for probe fixation is installed inside the positioning sleeve.

As a further optimization, the driving assembly comprises a lifting electric cylinder, a rotary cylinder, synchronous pulleys, a synchronous belt and tool holders, wherein the rotary cylinder is mounted on the lifting electric cylinder and driven to move up and down, the rotary cylinder drives the synchronous belt to move through a pair of synchronous pulleys, a pair of tool holders are fixedly positioned in staggered arrangement on opposite sides of the synchronous belt, the forming tools are installed within the tool holders, and the pair of forming tools are driven by the synchronous belt to translate and perform cutting operations on the self-rotating probes.

As a further optimization, the cutting section further comprises a guide rail and a fine adjustment knob, wherein the fine adjustment knob is arranged on the tool holder for adjusting the position of the forming tool, and the tool holder is slidably arranged on the guide rail

As a further optimization, the discharging mechanism comprises a discharging frame, a discharging manipulator and a discharging chuck, wherein the discharging frame is mounted on the machine platform adjacent to the discharging station, the discharging chuck is arranged at the free end of the discharging manipulator, and is driven by the discharging manipulator to transport the probe from the discharging station to the discharging frame.

As a further optimization, the beading machine further comprises an inspection mechanism, wherein an inspection station is provided on the rotary table between the beading station and the discharging station, an inspection mechanism is arranged on the machine platform adjacent to the inspection station, the inspection mechanism comprises an actuating cylinder and a force transducer, the force transducer is arranged at the free end of the actuating cylinder, and the force transducer presses downward on the probe at the inspection station to detect the spring-back force of the probe.

As a further optimization, comprising an inspection mechanism, an inspection station is provided on the rotary table between the beading station and the discharging station, an inspection mechanism is arranged on the machine platform adjacent to the inspection station, the inspection mechanism comprises an actuating cylinder and a force transducer, the force transducer is arranged at the free end of the actuating cylinder, and the force transducer presses downward on the probe at the inspection station to detect the spring-back force of the probe.

As a further optimization, a first visual inspection CCD is provided on the feeding mechanism; a second visual inspection CCD is provided on the discharging mechanism.

### BENEFICIAL EFFECTS OF THE INVENTION

### Beneficial Effects

1. By incorporating the feeding mechanism, beading mechanism, inspection mechanism and discharging mechanism, automatic feeding and discharging, beading and inspection operations of probes can be achieved, with high efficiency and high precision. The beading mechanism processes the self-rotating probe through a pair of reciprocating horizontally moving forming tools, achieving high beading efficiency, high beading precision, and excellent product quality;
2. In manual production, the yield rate is 95%, while the yield rate can reach 98% when using the fully automatic beading machine, representing a yield improvement of 3.0%. The per capita daily output in manual production is 2,500 pieces (one person operating one machine), whereas when using the automatic machine, the per capita daily output reaches 15,000 pieces (one person operating two machines), representing a 6.0-fold increase in per capita output. For automatically assembled products, the presence or absence of the spring can be automatically inspected at the time of product discharge, eliminating the need for a subsequent spring inspection process. Manual production inevitably introduces human factors (such as variations in assembly techniques and operator fatigue), whereas automatic production eliminates such issues, allowing the beading dimensional consistency to be controlled within 0.015 mm.

### BRIEF DESCRIPTION OF THE DRAWINGS

### Drawing Description

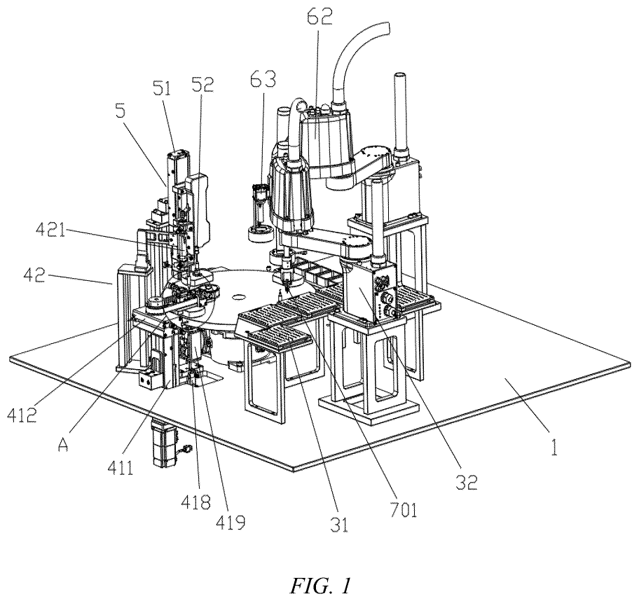

FIG. 1 is a structural diagram of the present invention.

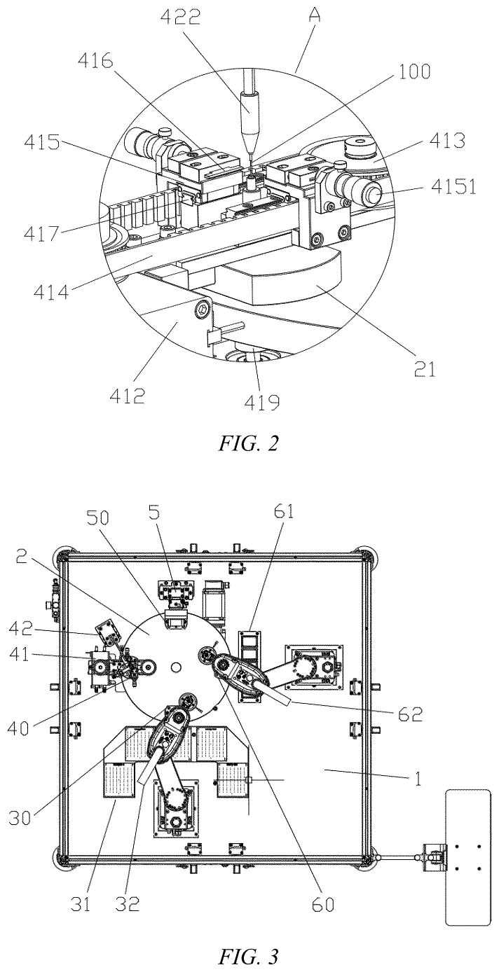

FIG. 2 is an enlarged view of section A in FIG. 1.

FIG. 3 is a top view of the present invention.

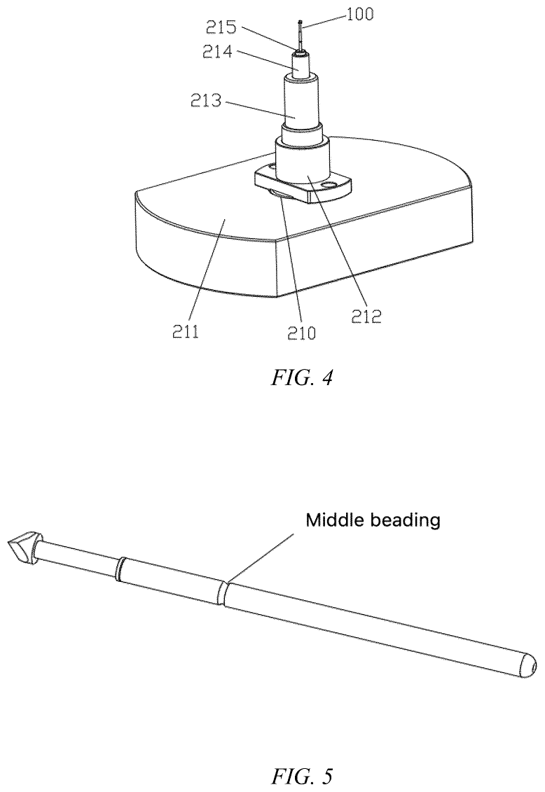

FIG. 4 is a structural diagram of the clamping fixture of the present invention.

FIG. 5 is a structural diagram of a micro probe having beading.

### EMBODIMENTS OF THE INVENTION

### Implementation of the Invention

The following are specific embodiments of the present invention. The technical solutions of the present invention are further described in conjunction with the accompanying drawings; however, the present invention is not limited to these embodiments.

As shown in FIGS. 1 to 5, the multi-station rotary fully automatic beading machine for micro probes comprises a machine platform 1, wherein a rotary table 2 is arranged on the machine platform 1. A plurality of clamping fixtures 21 for clamping probes 100 are arranged on the rotary table 2. The plurality of clamping fixtures 21 form a feeding station 30, a beading station 40, and a discharging station 60 along the rotation direction of the rotary table 2. A feeding mechanism is arranged on the machine platform 1 adjacent to the feeding station 30. The feeding mechanism is configured to feed probes to the feeding station 30. Specifically, the feeding mechanism comprises a feeding disc 31, a feeding manipulator 32, and a feeding chuck 701. The feeding disc 31 for containing beading probes is mounted on the machine platform 1 and arranged adjacent to the feeding station 30. The feeding chuck 701 is arranged at a free end of the feeding manipulator 32 and is driven by the feeding manipulator 32 to feed probes from the feeding disc 31 to the feeding station 30. A cutting mechanism 41 and a positioning mechanism 42 are arranged on the machine platform 1 adjacent to the beading station 40. The positioning mechanism 42 abuts against an upper end of the probe to position the probe in a vertical direction. The positioning mechanism comprises a pressing cylinder 421 and a pressing head 422. The pressing head 422 is arranged at a free end of the pressing cylinder 421 and is driven by the pressing cylinder 421 to move downward to abut against the upper end of the probe in the beading station 40, so that the probe remains stable in the vertical direction. The cutting mechanism 41 comprises a cutting portion and a rotating portion. The rotating portion drives the probe, which has been positioned in the vertical direction, to rotate on its own axis. Specifically, the rotating portion comprises a lifting cylinder 418, a rotary motor 419, and a magnet (not shown in the figure). The rotary motor 419 is arranged at a free end of the lifting cylinder 418. The magnet is arranged at a free end of the rotary motor 419. The lifting cylinder 418 drives the magnet to move upward and to be attracted to the clamping fixture. The clamping fixture 21 comprises a base 211, a bearing sleeve 212, a ferrous rotating sleeve 213, a positioning sleeve 214, and a protective sleeve 215. The base 211 is provided with a first through hole 210. The rotary table 2 is provided with a second through hole (not shown in the figure) coaxial with the first through hole 210. The ferrous rotating sleeve 213 is rotatably mounted within the bearing sleeve 212. A bottom end of the ferrous rotating sleeve 213 is located at the first through hole 210 and is attracted by the magnet. The positioning sleeve 214 is fixed within the ferrous rotating sleeve 213. The positioning sleeve 214 is internally mounted with a protective sleeve 215 for inserting and mounting the probe. Combined with the top end of the probe being pressed down by the pressing head, the probe can be relatively stably installed within the protective sleeve and can rotate at the same angle with the protective sleeve, thus enabling the rotary motor 419 to drive the magnet to rotate and drive the ferrous rotating sleeve and the probe to rotate coaxially, causing the probe to perform a self-rotation action. The cutting section comprises a driving assembly and forming tools 416, wherein the driving assembly comprises a lifting electric cylinder 411, a rotary cylinder 412, synchronous pulleys 413, a synchronous belt 414, and tool holders 415. The rotary cylinder 412 is mounted on the lifting electric cylinder 411 and driven to move up and down. The rotary cylinder 412 drives the synchronous belt 414 to move through a pair of synchronous pulleys 413. A pair of tool holders 415 are fixedly positioned in staggered arrangement on opposite sides of the synchronous belt 414. The forming tool 416 is installed within the tool holder 415. A pair of forming tools 416 are driven by the synchronous belt 414 to translate and cut the self-rotating probe, namely through two forming tools cutting the self-rotating probe from both sides thereof, thereby completing the beading operation.

The specific process of probe beading is as follows: the probe tip located within the protective sleeve is pressed down by the pressing head, the lifting cylinder drives the rotary motor upward, the magnet at the free end of the rotary motor attracts the ferrous rotating sleeve, whereby the rotary motor drives the ferrous rotating sleeve to rotate, achieving probe self-rotation. Simultaneously, the lifting electric cylinder operates, driving the rotary cylinder to descend until the forming tool reaches the same height as the position on the probe requiring beading. Since the pair of forming tools are offset and the initial position avoids the location where the forming tools are situated, the forming tools can descend to the required beading height position. The rotary cylinder drives the synchronous pulley to move the tool holder on the synchronous belt in the horizontal direction, enabling the pair of forming tools positioned on both sides of the probe to cut the self-rotating probe, thereby completing the beading operation. The lifting cylinder actuates, causing the magnet to disengage from the ferrous rotating sleeve, whereupon the pressing head rises. The lifting electric cylinder actuates, causing the forming tool to rise to the set height. Through rotation of the rotary table, the beading is fed to the next station, and the probe from the feeding station is fed to the beading station.

A discharging mechanism is arranged on the machine platform 1 adjacent to discharging station 60. The discharging mechanism moves the beaded probe away from the clamping fixture. The discharging mechanism comprises a discharging frame 61, a discharging manipulator 62 (having the same structure as the feeding manipulator), and a discharging chuck (having the same structure as the feeding chuck). The discharging frame 61 is mounted on machine platform 1 adjacent to the discharging station 60. The discharging chuck is arranged at the free end of discharging manipulator 62 and is driven by the discharging manipulator to feed the probe from discharging station 60 to discharging frame 61.

The cutting section further comprises a guide rail 417 and a fine adjustment knob 4151, wherein the fine adjustment knob 4151 is arranged on the tool holder 415 for adjusting the position of the forming tool 416, namely for adjusting the degree of penetration of the forming tool end portion, thereby controlling the depth of beading formation. The tool holder 415 is slidably arranged on the guide rail 417 to ensure precision of the tool holder driving the forming tool movement.

The apparatus further comprises an inspection mechanism, wherein the rotary table 2 comprises an inspection station 50 located between the beading station 40 and the discharging station 60. An inspection mechanism 5 is provided on the machine platform 1 adjacent to the inspection station 50, the inspection mechanism including an actuating cylinder 51 and a force transducer 52. The force transducer 52 is arranged at the free end of the actuating cylinder 51, and the force transducer 52 presses downward on the probe at the inspection station 50 to detect the spring-back force of the probe.

The feeding mechanism is equipped with a first visual detection CCD that captures material positions through visual positioning. After confirming coordinates, the feeding manipulator retrieves the product, then through feeding visual positioning to determine the position coordinates of the feeding station, the feeding manipulator places the retrieved product into the feeding station. The discharging mechanism is equipped with a second visual detection CCD 63 that performs product retrieval through the discharging manipulator after visual positioning. If the product force is qualified, the product will be placed into the discharging frame of the corresponding station; if the product force is unqualified, it will be directly placed into the defective material box.

### INDUSTRIAL APPLICABILITY

The specific embodiments described herein are merely illustrative examples of the spirit of the present invention. Those skilled in the art to which the present invention pertains may make various modifications or additions to the described specific embodiments or employ similar alternatives without departing from the spirit of the present invention or exceeding the scope defined by the appended claims.

1. A multi-station rotary fully automatic beading machine for micro probes, characterized in that comprising a machine platform, wherein a rotary table is arranged on the machine platform, a plurality of clamping fixtures for clamping probes are arranged on the rotary table, the plurality of clamping fixtures form a feeding station, beading station, and discharging station along a rotation direction of the rotary table, a feeding mechanism is arranged on the machine platform adjacent to the feeding station, the feeding mechanism is configured to feed probes to the feeding station, a cutting mechanism and a positioning mechanism are arranged on the machine platform adjacent to the beading station, the positioning mechanism abuts against an upper end of the probe to position the probe in a vertical direction, the cutting mechanism comprises a cutting section and rotating section, the rotating section drives the probe, which has been positioned in the vertical direction, to rotate on its own axis, the cutting section comprises a driving assembly and forming tools, the driving assembly drives the forming tool to translate and cut the self-rotating probe to form a beading, a discharging mechanism is arranged on the machine platform adjacent to the discharging station, the discharging mechanism removes the beaded probe from the clamping fixture.

2. The multi-station rotary fully automatic beading machine for micro probes according to claim 1, characterized in that the feeding mechanism comprises a feeding disc, a feeding manipulator and a feeding chuck, wherein the feeding disc is mounted on the machine platform adjacent to the feeding station, the feeding chuck is arranged at the free end of the feeding manipulator, and is driven by the feeding manipulator to feed probes from the feeding disc to the feeding station.

3. The multi-station rotary fully automatic beading machine for micro probes according to claim 1, characterized in that the positioning mechanism comprises a pressing cylinder and a pressing head, wherein the pressing head is arranged at the free end of the pressing cylinder, and is driven by the pressing cylinder to move downward and abut against the upper end of the probe at the beading station.

4. The multi-station rotary fully automatic beading machine for micro probes according to claim 3, characterized in that the rotating section comprises a lifting cylinder, a rotary motor, and a magnet, wherein the rotary motor is arranged at a free end of the lifting cylinder, the magnet is arranged at a free end of the rotary motor, the lifting cylinder drives the magnet to move upward with the clamping fixture, and the rotary motor drives the magnet to rotate, thereby driving the clamping fixture and probe to rotate coaxially.

5. The multi-station rotary fully automatic beading machine for micro probes according to claim 4, characterized in that the clamping fixture comprises a base, a bearing sleeve, a ferrous rotating sleeve, a positioning sleeve, and a protective sleeve, wherein a first through hole is provided on the base, a second through hole coaxial with the first through hole is provided on the rotary table, the ferrous rotating sleeve is rotatably mounted within the bearing sleeve, the bottom end of the ferrous rotating sleeve is located at the first through hole and is magnetically attracted by the magnet, the positioning sleeve is fixed inside the ferrous rotating sleeve, and a protective sleeve for probe fixation is installed inside the positioning sleeve.

6. The multi-station rotary fully automatic beading machine for micro probes according to claim 4, characterized in that the driving assembly comprises a lifting electric cylinder, a rotary cylinder, synchronous pulleys, a synchronous belt and tool holders, wherein the rotary cylinder is mounted on the lifting electric cylinder and driven to move up and down, the rotary cylinder drives the synchronous belt to move through a pair of synchronous pulleys, a pair of tool holders are fixedly positioned in staggered arrangement on opposite sides of the synchronous belt, the forming tools are installed within the tool holders, and the pair of forming tools are driven by the synchronous belt to translate and perform cutting operations on the self-rotating probes.

7. The multi-station rotary fully automatic beading machine for micro probes according to claim 6, characterized in that the cutting section further comprises a guide rail and a fine adjustment knob, wherein the fine adjustment knob is arranged on the tool holder for adjusting the position of the forming tool, and the tool holder is slidably arranged on the guide rail.

8. The multi-station rotary fully automatic beading machine for micro probes according to claim 1, characterized in that the discharging mechanism comprises a discharging frame, a discharging manipulator and a discharging chuck, wherein the discharging frame is mounted on the machine platform adjacent to the discharging station, the discharging chuck is arranged at the free end of the discharging manipulator, and is driven by the discharging manipulator to transport the probe from the discharging station to the discharging frame.

9. The multi-station rotary fully automatic beading machine for micro probes according to claim 1, characterized in that further comprising an inspection mechanism, wherein an inspection station is provided on the rotary table between the beading station and the discharging station, an inspection mechanism is arranged on the machine platform adjacent to the inspection station, the inspection mechanism comprises an actuating cylinder and a force transducer, the force transducer is arranged at the free end of the actuating cylinder, and the force transducer presses downward on the probe at the inspection station to detect the spring-back force of the probe.

10. The multi-station rotary fully automatic beading machine for micro probes according to claim 1, characterized in that a first visual inspection CCD is provided on the feeding mechanism; a second visual inspection CCD is provided on the discharging mechanism.
